(19) United States
(12) Patent Application Publication
(10) Pub. No.: US 2025/0176349 A1
(43) Pub. Date: May 29, 2025

(54) 3D/2D HYBRID PEROVSKITE SOLAR CELL AND ITS PREPARATION METHOD

(71) Applicant: NANJING UNIVERSITY OF AERONAUTICS AND ASTRONAUTICS, Nanjing City (CN)

(72) Inventors: Zhuhua ZHANG, Nanjing City (CN); Xiaoming ZHAO, Nanjing City (CN); Jinping ZHANG, Nanjing City (CN); Wanlin GUO, Nanjing City (CN); Bingkun TIAN, Nanjing City (CN)

(73) Assignee: NANJING UNIVERSITY OF AERONAUTICS AND ASTRONAUTICS, Nanjing City (CN)

(21) Appl. No.: 18/822,524

(22) Filed: Sep. 3, 2024

(30) Foreign Application Priority Data
Nov. 27, 2023 (CN) 2023116088204

(51) Int. Cl. H10K 30/40; H10K 85/50; H10K 101/00

(52) U.S. Cl. CPC H10K 30/40; H10K 85/50; H10K 2101/80

(57) ABSTRACT

The invention relates to a 3D/2D hybrid perovskite solar cell and its preparation method, which belongs to the field of preparation technology of perovskite material. By using aromatic organic spacer that can enhance the conjugation effect, a 3D/2D multi-dimensional perovskite is obtained, and its conjugation effect is enhanced, thereby improving its charge transport capability, which makes that the 3D/2D perovskite solar cell has both the high light absorption rate and charge transport capability of 3D perovskite material and the excellent stability of 2D perovskite material, so as to achieve efficient and stable 3D/2D multi-dimensional perovskite material and device.

### TECHNICAL FIELD

The invention belongs to the field of preparation technology of perovskite material, and specifically relates to a 3D/2D hybrid perovskite solar cell and its preparation method.

### BACKGROUND ART

Perovskite solar cells have become an emerging photovoltaic technology due to their excellent photoelectric property. Among them, compared with 3D perovskite materials, 2D perovskite materials have organic spacer cations with larger volume, less volatile and stronger hydrophobicity, showing enhanced thermal, water, chemical and environmental stability; however, the horizontal arrangement of organic layers of 2D perovskites seriously hinders carrier transport, 2D perovskite materials based on the organic cations with large volume often limit the extraction of photogenerated carrier and easily form charge extraction barrier, thus affecting charge stability and inhibiting the effective operation of the device. In order to solve this problem, the current research is to explore strategies such as shortening spacer cation, however, the insulating nature of these short ligands are still obstacles to the charge transport.

### SUMMARY OF THE INVENTION

The invention provides a 3D/2D hybrid perovskite solar cell and its preparation method, by using an aromatic organic spacer, a multi-dimensional 3D/2D perovskite is obtained to enhance its conjugation effect, thereby improving its charge transfer capability and making the 3D/2D perovskite solar cell combines the high light absorption rate and charge transfer capability of the 3D perovskite materials and the excellent stability of the 2D perovskite materials, so as to achieve efficient and stable 3D/2D perovskite material and device.

In order to achieve the above purpose, the invention adopts the following technical scheme:

A preparation method for 3D/2D hybrid perovskite solar cell, comprising the following steps:
S1: cleaning and getting a clean conductive substrate;
S2: preparing a core functional layer of the perovskite solar cell on a substrate; among them, preparing a perovskite light-absorption layer by using a one-step deposition method, so as to synthesize a 3D/2D perovskite film, dissolving a 2D perovskite single crystal and a 3D perovskite precursor in a mixed solvent, and then spin-coating the mixed solvent on a conductive substrate, then making the substrate anneal at 100-150° C. for 5-60 min;
S3: preparing a top electrode on the core functional layer to obtain the 3D/2D hybrid perovskite solar cell;

In above steps, the core functional layer in S2 is composed of hole transport layer, perovskite light-absorption layer and electron transport layer.

A structure of perovskite solar cell can be either a formal structure or an inverted structure: the core functional layers of the formal structure, from the substrate to the top, are sequentially the electron transport layer, the perovskite light-absorption layer and the hole transport layer; conversely, an arrangement order of the core functional layer of the inverted structure is the hole transport layer, the perovskite light-absorption layer and the electron transport layer from the substrate to the top.

The substrate can be either a flexible film or a rigid glass; an appearance of the perovskite solar cell is black or colored or transparent;

The electron transport layer is one or more of semiconductors with a valence band (VB) between −3.9 eV and −8.0 eV, comprising but not limited to TiO₂, SnO₂, ZnO, C₆₀, PCBM, ITIC;

The hole transport layer is one or more of semiconductors with a conduction band (CB) between −4.0 eV and −6.0 eV, comprising but not limited to NiOₓ, WO₃, V₂O₅, PTAA, P3HT, Spiro-OMeTAD;

The perovskite light-absorption layer is a 3D/2D mixed perovskite, and 2D perovskite material is a 2D halide perovskite containing conjugated molecular bonds, its structure is A′ₘAₙ₋₁BₙX₃ₙ₊₁, wherein A′ denotes a monovalent or divalent organic cation that separates adjacent perovskite layers, and n is a number of perovskite layers between the A′ organic layers; A is one or more of cesium (Cs), methylamine (MA), methylamine (FA); B is one or more of phenylethyl-L4-azacyclohexane (PEA), (2-(naphthalene-2-yl)ethyl)-L4-azacyclohexane (NEA), (4-(4,5-dihydropyrene-2-yl)butyl)-L4-azacyclohexane (PyBA); X is one or more of I, Br, Cl, F; 3D perovskite is a 3D halide perovskite with a chemical structure of ABX₃, wherein A is one or more of Cs, MA and FA, B is one or more of Pb, Sn and Ge, and X is one or more of I, Br, Cl and F.

A 3D/2D hybrid perovskite solar cell, the arrangement order from bottom to top is the conductive substrate, the core functional layer and the top electrode; the arrangement order of the core functional layer from bottom to top is the electron transport layer, the perovskite absorption layer, the hole transport layer, or the hole transport layer, the perovskite absorption layer, the electron transport layer; the perovskite light-absorption layer is a 3D/2D mixed perovskite film with large conjugated molecules, among them, the 2D perovskite material is evenly distributed on a surface and grain boundaries of the 3D material, and the 2D perovskite material contains organic spacer cations with large conjugated molecular bonds.

Beneficial effects: the invention provides a 3D/2D mixed perovskite solar cell and its preparation method, compared with the existing technology, it has the following advantages:
1. The conventional 3D/2D perovskite solar cells suffer from limited charge transfer capability and poor device operation stability, the invention forms an organic spacer layer with large conjugated molecules in the 3D/2D perovskite film, which achieves the dual beneficial effects of enhancing its moisture resistance and forming a good environment and operational stability, benefiting from the strong chemical bond of the conjugated molecule, the prepared photoelectric device has the advantages of high photoelectric conversion efficiency and enhanced operational stability.
2. The 3D/2D perovskite film prepared based on the invention features strong conjugated chemical bonds, which is conducive to the charge transport in the perovskite light-absorption layer, the photoelectric conversion rate (PCE) of the treated perovskite solar cell can reach 24.4% and maintain 90% of the initial PCE after 3000 hours of operation.
3. The processing method used in the invention has simple operation and low processing cost, and the prepared perovskite solar cell has commercial application potential.

### BRIEF DESCRIPTION OF DRAWINGS

FIG. 1 is the schematic diagram of the 3D/2D perovskite film material prepared in Embodiments 1-3 of the invention;

FIG. 2 is the photoluminescence (PL) spectra excited from the film side of the 3D/2D perovskite film in Ratio 1 of the invention.

FIG. 3 is the current density-voltage (J-V) curve diagram of the perovskite solar cell in Embodiments 1-3 and Ratio 1 of the invention;

FIG. 4 is the capability test result diagram for a large-area (24.8 cm²) of perovskite solar module prepared by the method of the Embodiment 3 of the invention (the illustration is an optical image of the solar module);

FIG. 5 is the transient photocurrent measurement diagram of perovskite solar cell in Embodiments 1-3 and the Ratio 1 of the invention;

FIG. 6 shows the space charge limited current (SCLC) measurement for the pure hole device of perovskite solar cell in Embodiments 1-3 and Ratio 1 of the invention.

FIG. 7 is the function diagram of the aging time of standardized PCE as unencapsulated PSCs in 25° C. and 80% R.H. air in Embodiments 1-3 and Ratio 1 of the invention.

FIG. 8 is the function diagram of the aging time of PCE as encapsulated PSCs in Embodiments 1-3 and Ratio 1 of the invention during the humidity-heat test (i.e., 85° C. and 85% R.H.).

FIG. 9 shows the maximum power point tracking (MPPT) result diagram of the encapsulated PSCs over approximately 2000 hours under the simulated solar illumination in 40° C. ambient air in Embodiments 1-3 and Ratio 1 of the invention.

### DETAILED DESCRIPTION OF THE INVENTION

The following is a detailed description of the invention in combination with drawings and specific embodiments:

### Embodiment 1

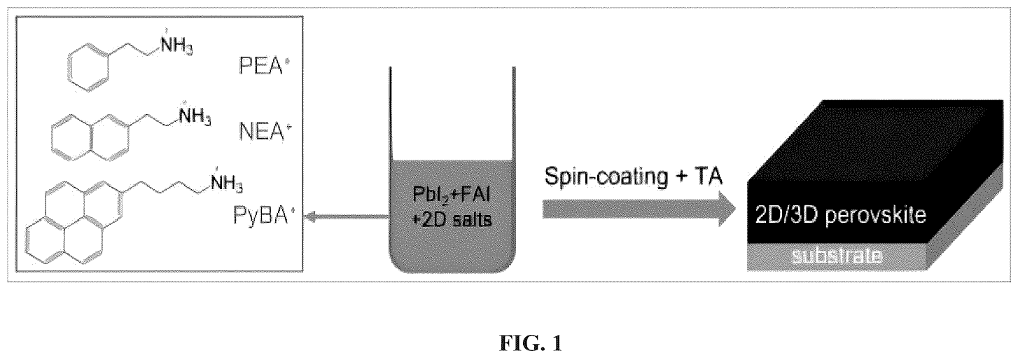

As shown in FIG. 1, a 3D/2D hybrid perovskite solar cell and its preparation method comprises the following steps:

The ITO glass substrate is washed by detergent, acetone and isopropyl alcohol (IPA) in turn, and each step is washed for 15 min, then the substrate is dried by nitrogen and treated by ultraviolet-ozone for 30 min; the SnO₂ nanoparticle water solution with a mass concentration of 3% is then spin-coated on the substrate at a speed of 3000 rpm for 30 seconds, and the substrate is annealed on a 150° C. hot plate for 30 min. The 67 mM KCl solution is further spin-coated at a speed of 5000 rpm for 30 seconds, and the substrate is annealed at 150° C. for 15 minutes, after cooling to room temperature, it is treated by ultraviolet-ozone for 30 min. 1.4 M (FAPbI₃)_{0.98} (PEA₂PbI₄)_{0.02} is dissolved in DMF: DMSO (the volume ratio is 9:1) mixed solvent and spin-coated onto the substrate at a speed of 5500 rpm for 30 s; 8 seconds before the end, 1 mL of ether as anti-solvent is dropped onto the substrate, and then the sample is annealed at 150° C. for 15 min. During the entire deposition process, the ambient humidity is maintained at 35%, in a nitrogen environment, the hole transport layer Spiro-OMeTAD solution is spin-coated on the top of the perovskite light-absorption layer at a speed of 3000 rpm for 30 seconds. Finally, the Au electrode is evaporated to obtain a 3D/2D hybrid perovskite solar cell with the formal structure.

### Embodiment 2

The difference is that (FAPbI₃)_{0.98}(PEA₂PbI₄)_{0.02} is replaced by (FAPbI₃)_{0.98} (NEA₂ PbI₄)_{0.02.}

### Embodiment 3

The present embodiment is basically the same as Embodiment 1, the difference is that (FAPbI₃)_{0.98}(PEA₂PbI₄)_{0.02} is replaced by (FAPbI₃)_{0.98}(PyBA₂PbI₄)_{0.02}.

### Ratio 1.

The present ratio is basically the same as Embodiment 1, and the difference is that (FAPbI₃)_{0.98}(PEA₂PbI₄)_{0.02} is replaced by 3D perovskite material FAPbI₃.

### Embodiment 4

A method for improving the charge transport capability of 3D/2D hybrid perovskite solar cell, comprising the following steps:

The ITO substrate is carved by laser as PI line, the ITO glass substrate is washed with detergent, acetone and IPA in turn, and each step is washed for 15 min, after it is dried by nitrogen and treated by ultraviolet-ozone, the PTAA layer is coated on the ITO glass substrate at a speed of 15 mm/s, the gap between the blade and the ITO substrate is 100 μm, the PTAA is dissolved in toluene to prepare the PTAA solution with a concentration of 2 mg/ml, 1.3M (FAPbI₃)_{0.98}(PyBA₂PbI₄)_{0.02} is dissolved in the mixed solvent of DMF and NMP (the volume ratio is 1:1), subsequently, the precursor solution is coated on a PTAA-coated ITO glass substrate at a speed of 15 mm/s, with a gap of 300 μm, and a nitrogen knife is used during blade coating, after that, the perovskite film is annealed on a 150° C. hot plate in air (35% R.H.) for 15 min, the C₆₀ with the thickness of 30 nm and the BCP with the thickness of 5 nm are thermally evaporated on the surface of the sample, and the deposited layer is carved by laser as P2 line, then, the copper with the thickness of 100 nm is thermally evaporated as an electrode to obtain a 3D/2D hybrid perovskite solar cell with an inverted structure.

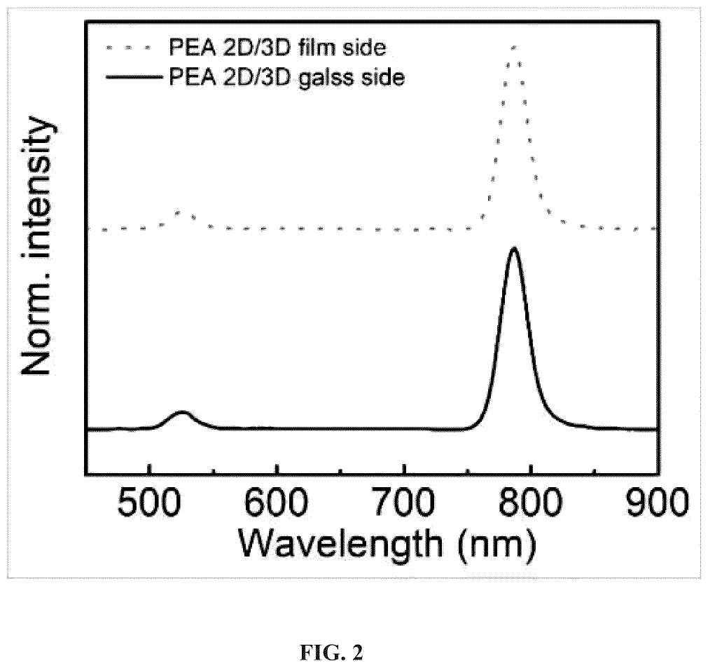

As shown in FIG. 2, the photoluminescence (PL) spectra excited from the film side of the 3D/2D perovskite film of Embodiment 1 indicates that the newly formed 2D structure is evenly distributed throughout the bulk film.

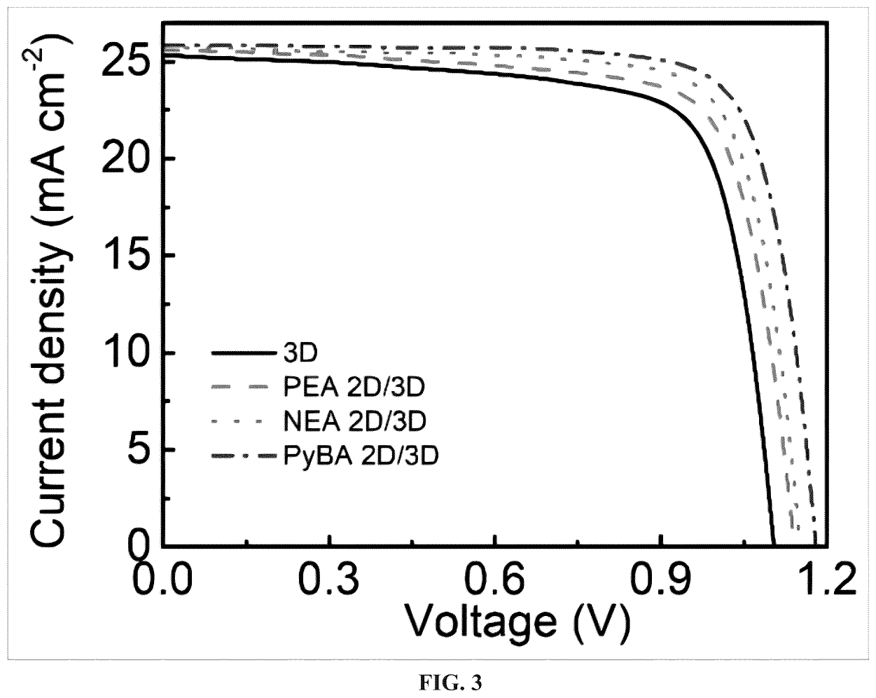

FIG. 3 is the current density-voltage (J-V) curve diagram of the perovskite solar cell in Embodiments 1-3 and Ratio 1 of the invention; it can be seen from the diagram that the photoelectric conversion efficiency (PCE) of the original 3D PSC is 20.9%, while the optimal PCE of the 3D/2D PSC increases to 22.1% (PEA), 23.1% (NEA) and 24.4% (PyBA) respectively, indicating that the efficiency of the solar cell increases with the degree of molecular conjugation.

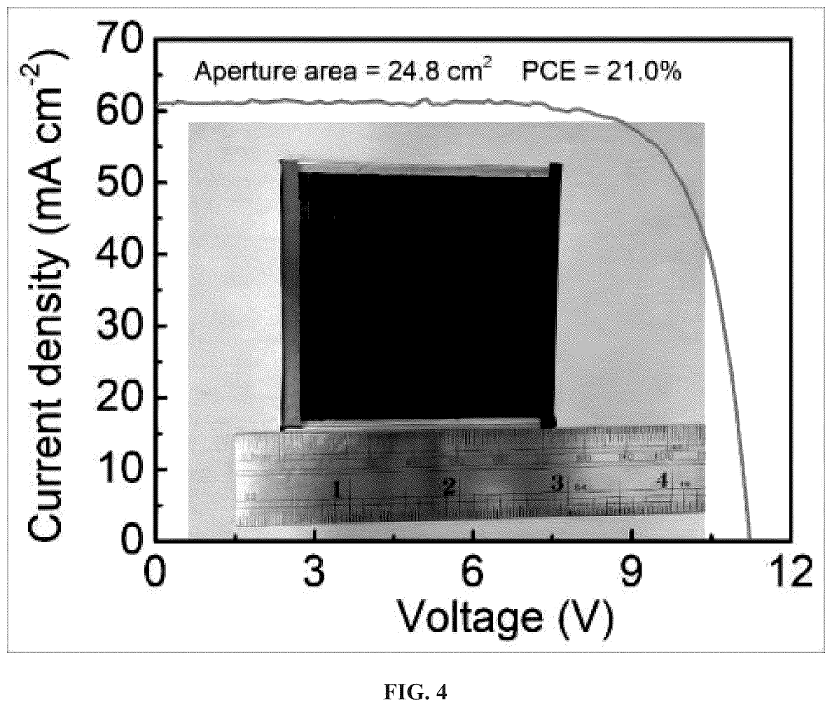

FIG. 4 is the capability test result diagram for a large-area (24.8 cm²) perovskite solar module prepared by the method of Embodiment 3 of the invention (the illustration is an optical image of solar module), the open circuit voltage (V_{OC}) and short circuit current (I_{SC}) of the perovskite solar module are 11.3 V and 60.8 mA respectively, the fill factor (FF) and PCE are 0.76 and 21% respectively.

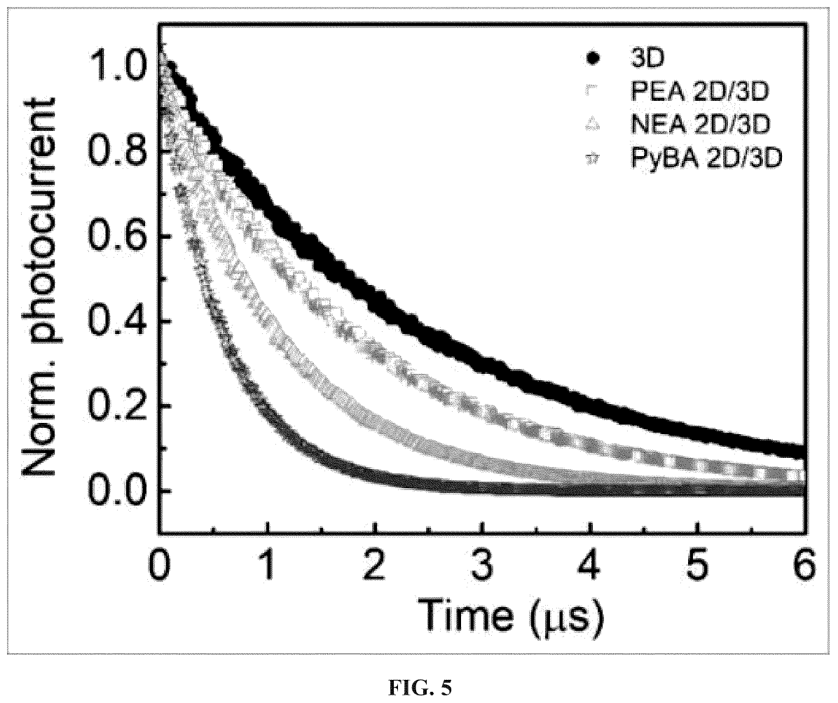

FIG. 5 is the transient photocurrent measurement diagram of the perovskite solar cell in Embodiments 1-3 and Ratio 1 of the invention, the photocurrent of the 3D/2D PSC with 2D spacer containing larger conjugated molecules decays faster, which indicates that the 2D spacer with larger conjugated molecules can significantly improve the carrier extraction rate and enhance the charge transport capability of the 3D/2D perovskite.

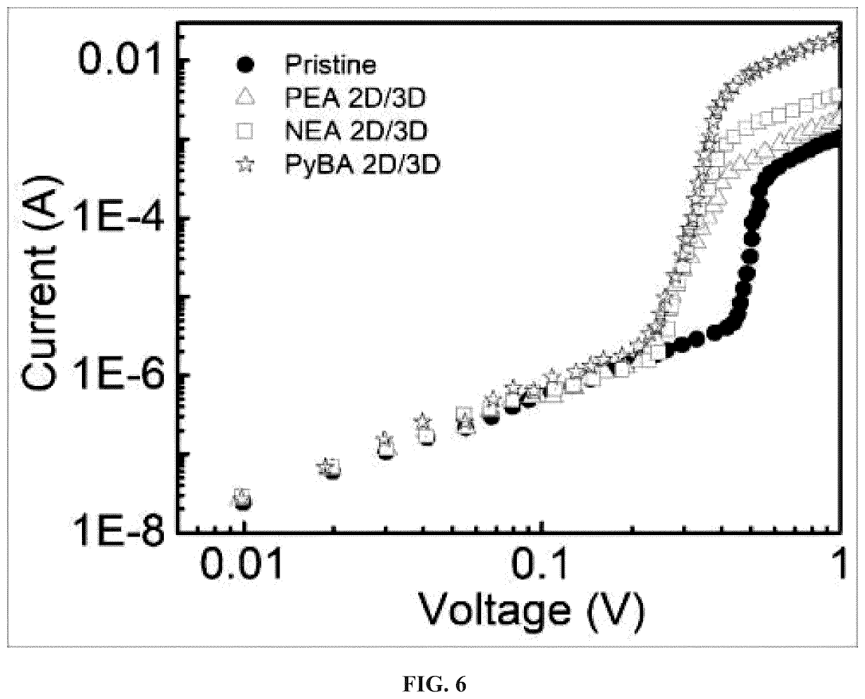

FIG. 6 shows the space charge limited current (SCLC) measurement for the pure hole device of the perovskite solar cell in Embodiments 1-3 and Ratio 1 of the invention, the hole mobility is enhanced in the order of PyBA 3D/2D>NEA 3D/2D>PEA 3D/2D>original 3D, which indicates that the 2D spacer with larger conjugated molecule enhances the charge transport ability of the 3D/2D perovskite by increasing the hole mobility.

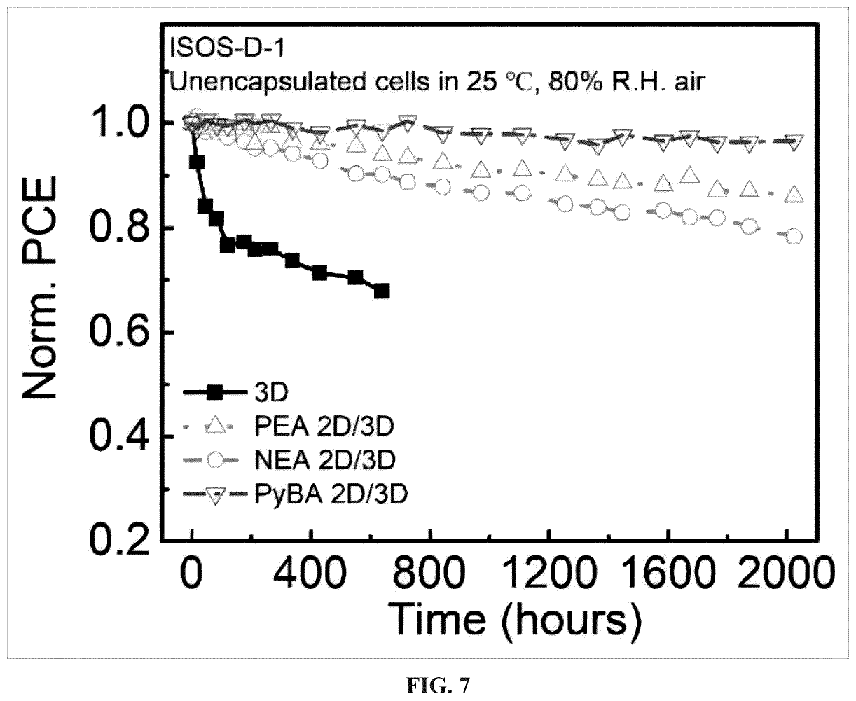

FIG. 7 is the function diagram of the aging time of standardized PCE as unencapsulated PSCs in 25° C. and 80% R.H. air in Embodiments 1-3 and Ratio 1 of the invention, compared with the original 3D cell, the stability of 3D/2D perovskite solar cells containing 2D perovskite is significantly improved, indicating enhanced moisture resistance.

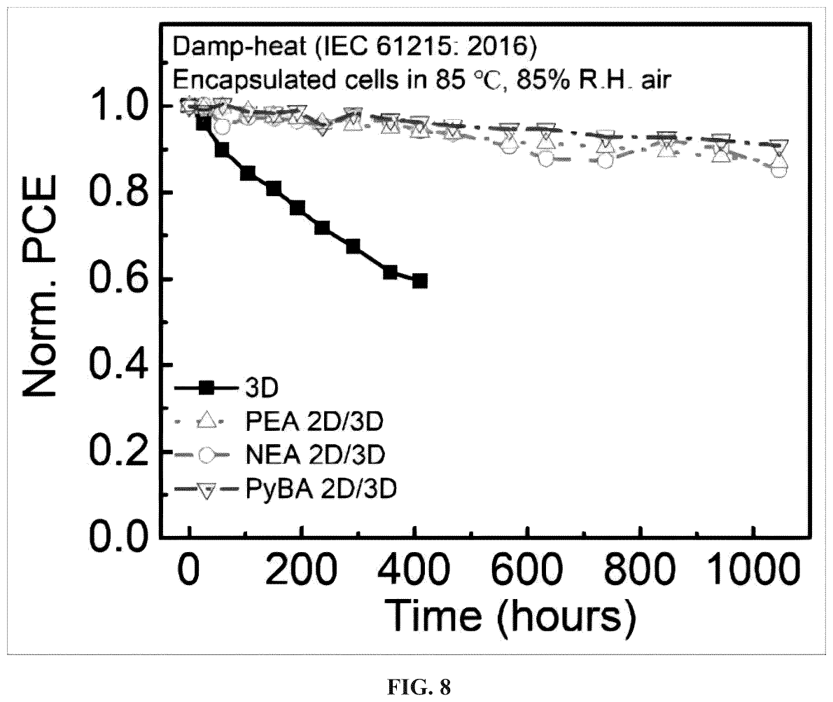

FIG. 8 is the function diagram of the aging time of PCE as encapsulated PSCs during the hygrothermal test in Embodiments 1-3 and Ratio 1 of the invention (i.e., 85° C. and 85% R.H.), compared with the original 3D perovskite solar cell, the stability of 3D/2D perovskite solar cells containing 2D perovskite is significantly improved, indicating that the incorporation of 2D perovskite passivates the surface defects and prevents thermal decomposition.

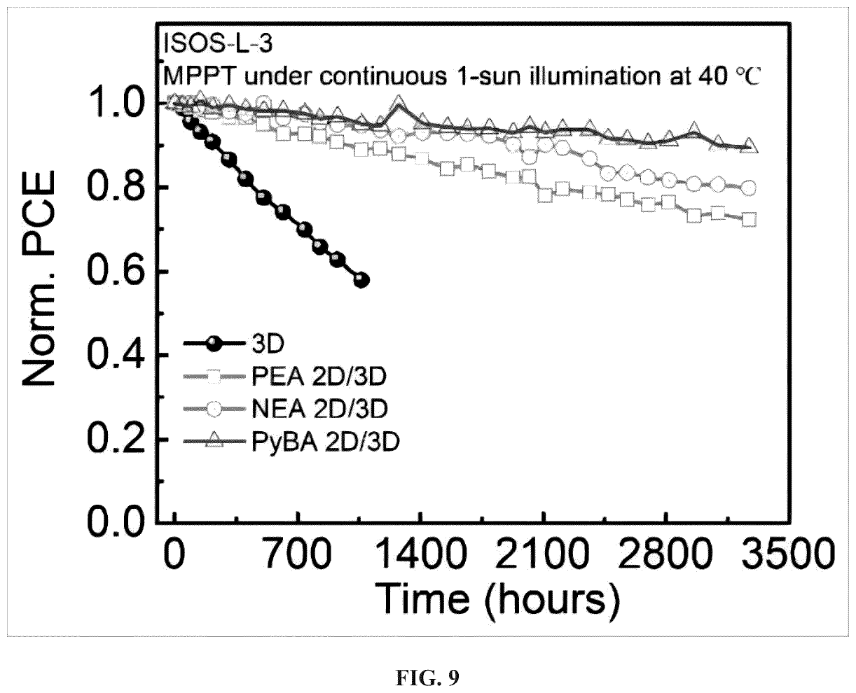

FIG. 9 shows the maximum power point tracking (MPPT) diagram of the encapsulated PSCs over approximately 2000 hours under the simulated solar illumination at 40° C. ambient air in Embodiments 1-3 and Ratio 1 of the invention, after 400 hours, the original solar cell losses more than 20% of the initial PCE, while the 3D/2D perovskite solar cell shows significantly improved operational stability, and remains more than 73% (PEA), 80% (NEA) and 90% (PyBA) of the initial PCE after 3000 hours of operation, indicating that the incorporation of 2D perovskite effectively improves the operational stability of PSC.

The above are only the preferred implementation methods of the invention, it should be pointed out that for the ordinary technicians in the technical field, some improvements can be made without breaking away from the principle of the invention, and these improvements should also be regarded as the protection scope of the invention.

What is claimed is:

1. A 3D/2D hybrid perovskite solar cell, an arrangement order from bottom to top is a conductive substrate, a core functional layer, and a top electrode, wherein the perovskite light-absorption layer in the core functional layer is a 3D/2D mixed perovskite film with larger conjugated molecules, wherein a 2D perovskite material is evenly distributed on a surface and a grain boundary of a 3D perovskite material, wherein the 2D perovskite material contains organic spacer cation with larger conjugated molecular bonds.

2. The 3D/2D hybrid perovskite solar cell according to claim 1, the core functional layer can be either a formal structure or an inverted structure.

3. The 3D/2D hybrid perovskite solar cell according to claim 2, an arrangement order of the formal structure is electron transport layer, perovskite light-absorption layer, and hole transport layer from bottom to top.

4. The 3D/2D hybrid perovskite solar cell according to claim 2, an arrangement order of the inverted structure is hole transport layer, perovskite light-absorption layer, and electron transport layer from bottom to top.

5. The 3D/2D hybrid perovskite solar cell according to claim 1, the electron transport layer is one or more of semiconductors with a valence band (VB) between −3.9 eV and −8.0 eV; the hole transport layer is one or more of the semiconductors with a conduction band (CB) between −4.0 eV and −6.0 eV.

6. The 3D/2D hybrid perovskite solar cell according to claim 3, the 2D perovskite material is a 2D halide perovskite containing conjugated molecular bonds, its structure is A′ₘAₙ₋₁BₙX₃ₙ₊₁, wherein A′ denotes a monovalent or divalent organic cation that separates adjacent perovskite layers, and n is a number of perovskite layers between the A′ organic layers; A is one or more of Cs, MA, FA, B is one or more of PEA, NEA, PyBA, X is one or more of I, Br, Cl, F.

7. The 3D/2D hybrid perovskite solar cell according to claim 3, the 3D perovskite is a 3D halide perovskite with a chemical structure of ABX₃, wherein A is one or more of Cs, MA and FA, B is one or more of Pb, Sn and Ge, and X is one or more of I, Br, Cl and F.

8. A preparation method for 3D/2D hybrid perovskite solar cell according to claim 1, comprising the following steps:
S1: cleaning and getting a clean conductive substrate;
S2: preparing a core functional layer of the perovskite solar cell on a substrate; among them, preparing the perovskite light-absorption layer by using a one-step deposition method, so as to synthesize a 3D/2D perovskite film;
S3: preparing a top electrode on the core functional layer to obtain the 3D/2D hybrid perovskite solar cell.

9. The preparation method for 3D/2D hybrid perovskite solar cell according to claim 8, a preparation of the perovskite light-absorption layer comprises the following steps: dissolving a 2D perovskite single crystal and a 3D perovskite precursor in a mixed solvent, and then spin-coating the mixed solvent on the conductive substrate, then making the substrate anneal at 100-150° C. for 5-60 min.

10. The 3D/2D hybrid perovskite solar cell according to claim 4, the 2D perovskite material is a 2D halide perovskite containing conjugated molecular bonds, its structure is A′ₘAₙ₋₁BₙX₃ₙ₊₁, wherein A′ denotes a monovalent or divalent organic cation that separates adjacent perovskite layers, and n is a number of perovskite layers between the A′ organic layers; A is one or more of Cs, MA, FA, B is one or more of PEA, NEA, PyBA, X is one or more of I, Br, Cl, F.

11. The 3D/2D hybrid perovskite solar cell according to claim 4, the 3D perovskite is a 3D halide perovskite with a chemical structure of ABX₃, wherein A is one or more of Cs, MA and FA, B is one or more of Pb, Sn and Ge, and X is one or more of I, Br, Cl and F.
